(19) United States
(12) Patent Application Publication
(10) Pub. No.: US 2025/0248272 A1
(43) Pub. Date: Jul. 31, 2025

(54) OLED COLOR PATTERNING BASED ON PHOTOLITHOGRAPHY AND CHEMICAL MECHANICAL POLISHING

(71) Applicant: Applied Materials, Inc., Santa Clara, CA (US)

(72) Inventors: Ji Young CHOUNG, Hwaseong-si (KR); Yu-Hsin LIN, Zhubei City (TW); Chung-chia CHEN, Hsinchu City (TW); Minhyung PARK, Seongnam-Si (KR); Sheng-Wen WANG, Tainan City (TW); Si Kyoung KIM, Gwangju-si (KR); Indrajit LAHIRI, Santa Clara, CA (US)

(21) Appl. No.: 18/805,004

(22) Filed: Aug. 14, 2024

Related U.S. Application Data
(60) Provisional application No. 63/627,611, filed on Jan. 31, 2024.

(51) Int. Cl. H10K 59/80; H10K 59/12; H10K 59/122

(52) U.S. Cl. CPC H10K 59/873; H10K 59/1201; H10K 59/122

(57) ABSTRACT

In one or more embodiments, a sub-pixel includes adjacent overhang structures disposed over a substrate. Each overhang structure has an upper portion having a top surface and a bottom surface. The bottom surface wider than a top surface of a lower portion. Adjacent overhang structures define an opening of the sub-pixel. An anode is disposed over the substrate between the adjacent overhang structures. An organic light-emitting diode (OLED) material disposed over the anode. A cathode is disposed over the OLED material. An encapsulation layer is disposed over the cathode. The encapsulation layer extends under at least a portion of the overhang structures along a sidewall of the lower portion and contacts the bottom surface of the upper portion of the overhang structures.

### CROSS-REFERENCE TO RELATED APPLICATIONS

This application claims priority of Application 63/627,611 filed on Jan. 31, 2024, which is herein incorporated by reference in its entirety.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are sub-pixel circuits and methods of forming sub-pixel circuits to increase pixel-per-inch and provide improved OLED performance.

### SUMMARY

Embodiments described herein generally relate to a display. More specifically, embodiments described herein relate to sub-pixel circuits and methods of forming sub-pixel circuits that may be utilized in a display such as an organic light-emitting diode (OLED) display.

In one or more embodiments, a sub-pixel includes adjacent overhang structures disposed over a substrate. Each overhang structure has an upper portion having a top surface and a bottom surface. The bottom surface wider than a top surface of a lower portion. Adjacent overhang structures define an opening of the sub-pixel. An anode is disposed over the substrate between the adjacent overhang structures. An organic light-emitting diode (OLED) material disposed over the anode. A cathode is disposed over the OLED material. An encapsulation layer is disposed over the cathode. The encapsulation layer extends under at least a portion of the overhang structures along a sidewall of the lower portion and contacts the bottom surface of the upper portion of the overhang structures. The encapsulation layer has an uppermost surface coplanar to the top surface of the upper portion of the adjacent overhang structures. An intermediate encapsulation layer is deposited over the encapsulation layer. The intermediate encapsulation layer extends over upper portion of the overhang structure. A global encapsulation layer is deposited over the intermediate encapsulation layer.

In one or more embodiments, a device includes a plurality of sub-pixels. The plurality of sub-pixels include at least a first sub-pixel and a second sub-pixel. The first sub-pixel and the second sub-pixel each include adjacent overhang structures disposed over a substrate. Each overhang structure has an upper portion having a top surface and a bottom surface. The bottom surface is wider than a top surface of a lower portion. The adjacent overhang structures define an opening of the sub-pixel. An anode is disposed over the substrate between the adjacent overhang structures. An organic light-emitting diode (OLED) material disposed over the anode. A cathode is disposed over the OLED material. An encapsulation layer is disposed over the cathode. The encapsulation layer extends under at least a portion of the overhang structures along a sidewall of the lower portion and contacts the bottom surface of the upper portion of the overhang structures. The encapsulation layer has an uppermost surface coplanar to the top surface of the upper portion of the adjacent overhang structures. An intermediate encapsulation layer is deposited over the encapsulation layer. The intermediate encapsulation layer extends over upper portion of the overhang structure. A global encapsulation layer is deposited over the intermediate encapsulation layer.

In one or more embodiments, a method of manufacturing a sub-pixel device includes depositing a plurality of anodes over a substrate and patterning a plurality of pixel defining layer (PDL) structures over the substrate. The method further includes depositing a lower portion material over the substrate, depositing an upper portion material over the substrate, and forming a first sub-pixel opening in the lower portion material and the upper portion material. The first sub-pixel opening defines adjacent overhang structures. The adjacent overhang structures have an upper portion having a top surface and a bottom surface. The bottom surface wider than a top surface of a lower portion. The method further includes performing a first deposition process. The first deposition process includes depositing a first OLED material, a first cathode, and a first encapsulation layer within the first sub-pixel opening. A portion of the first OLED material, the first cathode, and the first encapsulation layer extend over an upper surface of the upper portion material. The method further includes performing a first CMP process to remove the portion of the first OLED material, the first cathode, and the first encapsulation layer extending over an upper surface of the upper portion material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit, according to one or more embodiments.

FIG. 1B is a schematic, top view of a sub-pixel circuit having a dot-type architecture, according to one or more embodiments.

FIG. 1C is a schematic, top view of a sub-pixel circuit having a line-type architecture, according to one or more embodiments.

FIG. 2 is a flow a flow diagram of an on-demand CMP method for forming a sub-pixel circuit, according to one or more embodiments.

FIGS. 3A-4N are schematic, cross-sectional views of a substrate during the method for forming the sub-pixel circuit, according to embodiments.

FIGS. 4A-4F are close-up schematic, cross-sectional views of an upper portion of the overhang structure of a sub-pixel circuit, according to embodiments.

FIGS. 5A-5F are close-up schematic, cross-sectional views of an upper portion of the overhang structure of a sub-pixel circuit, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In one embodiment, which can be combined with other embodiments described herein, the display is a bottom emission (BE) or a top emission (TE) OLED display. In another embodiment, which can be combined with other embodiments described herein, the display is a passive-matrix (PM) or an active matrix (AM) OLED display.

A first exemplary embodiment of the embodiments described herein includes a sub-pixel circuit having a dot-type architecture. A second exemplary embodiment of the embodiments described herein includes a sub-pixel circuit having a line-type architecture. Each of the embodiments (including the exemplary embodiments) described herein of the sub-pixel circuit include a plurality of sub-pixels with each of the sub-pixels defined by adjacent inorganic overhang structures that are permanent to the sub-pixel circuit. While the Figures depict two sub-pixels, with each sub-pixel defined by adjacent inorganic overhang structures, the sub-pixel circuit of the embodiments described herein include a plurality of sub-pixels, such as two or more sub-pixels, such as three or more sub-pixels. Each sub-pixel has the OLED material configured to emit a white, red, green, blue or other color light when energized. E.g., the OLED material of a first sub-pixel emits a green light when energized, the OLED material of a second sub-pixel emits a red light when energized, and the OLED material of a third sub-pixel emits a blue light when energized.

The inorganic overhang structures are permanent to the sub-pixel circuit and include at least an upper portion disposed on a lower portion. A first configuration of the inorganic overhang structures includes the upper portion of a non-conductive inorganic material and the lower portion of a conductive inorganic material. A second configuration of the inorganic overhang structures includes the upper portion of a conductive inorganic material and the lower portion of a conductive inorganic material. A third configuration of the inorganic overhang structures includes the upper portion of a non-conductive inorganic material, the lower portion of a non-conductive inorganic material, and an assistant cathode disposed under the lower portion. A fourth configuration of the inorganic overhang structures includes the upper portion of a conductive inorganic material, the lower portion of a non-conductive inorganic material, and an assistant cathode disposed under the lower portion. Any of the exemplary embodiments include inorganic overhang structures of at least one of the first, second, third, or fourth configurations.

The adjacent inorganic overhang structures defining each sub-pixel of the sub-pixel circuit of the display provide for formation of the sub-pixel circuit using evaporation deposition and provide for the inorganic overhang structures to remain in place after the sub-pixel circuit is formed. Evaporation deposition may be utilized for deposition of an OLED material (including a hole injection layer (HIL), a hole transport layer (HTL), an emissive layer (EML), and an electron transport layer (ETL)) and cathode. One or more of an encapsulation layer, and a global passivation layer may be disposed via evaporation deposition. In embodiments including one or more capping layers, the capping layers are disposed between the cathode and the encapsulation layer. The inorganic overhang structures define deposition angles, i.e., provide for a shadowing effect during evaporation deposition, for each of the OLED material and the cathode such the OLED material does not contact the lower portion (and assistant cathode according to embodiments with the third and fourth configurations) and the cathode contacts the lower portion according to the first and second configurations or at least the assistant cathode of the third and fourth configurations. In one or more embodiments, both the OLED material and the cathode contact the lower portion. The encapsulation layer of a respective sub-pixel is disposed over the cathode with the encapsulation layer extending under at least a portion of each of the adjacent inorganic overhang structures and along a sidewall of each of the adjacent inorganic overhang structures.

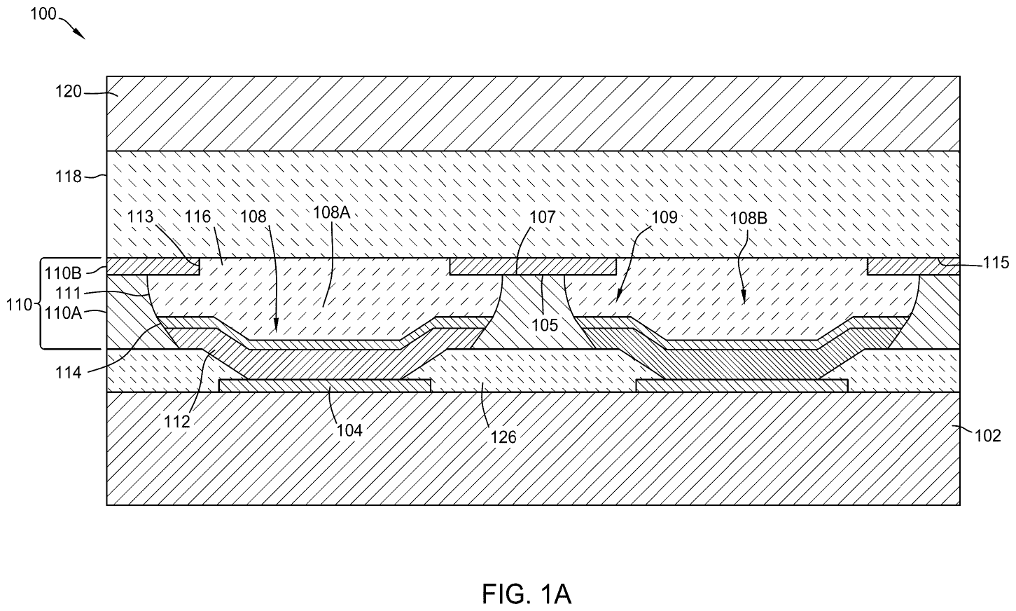

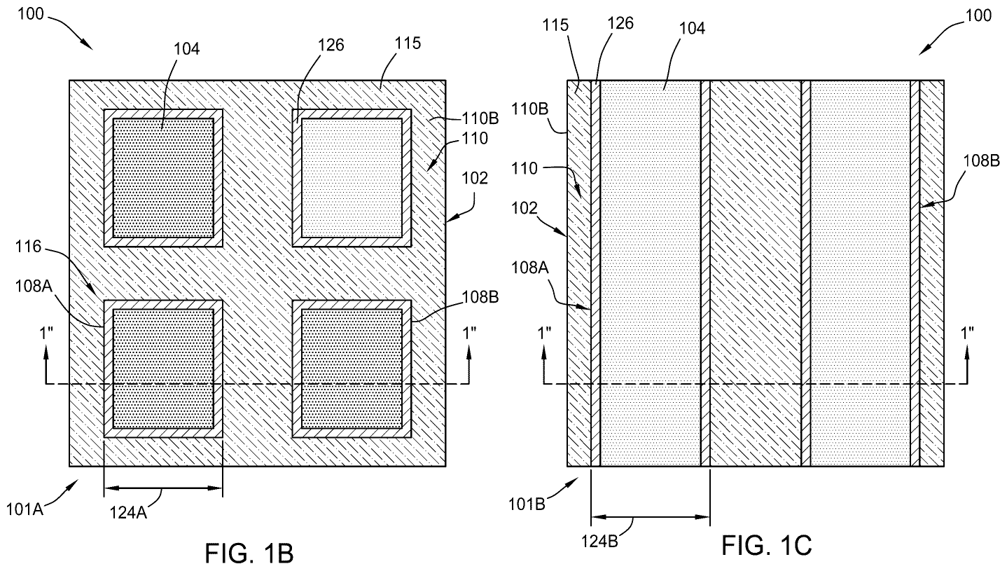

FIG. 1A is a schematic, cross-sectional view of a sub-pixel circuit 100, according to one or more embodiments. The sub-pixel circuit 100 may have either a dot-type architecture 101A as shown in FIG. 1B, or a line type architecture 101B as shown in FIG. 1C. The cross-sectional view of FIG. 1A is taken along section line 1″-1″ of FIGS. 1B and 1C.

The sub-pixel circuit 100 includes a substrate 102. Metal layers 104 may be patterned on or over the substrate 102 and are defined by adjacent pixel-defining layer (PDL) structures 126 disposed on or over the substrate 102. In one embodiment, which can be combined other embodiments described herein, the metal layers 104 are pre-patterned on or over the substrate 102. E.g., the substrate 102 is a pre-patterned indium tin oxide (ITO) glass substrate. The metal layers 104 are configured to operate anodes of respective sub-pixels. The metal layers 104 include, but are not limited to, chromium, titanium, gold, silver, copper, aluminum, ITO, a combination thereof, or other suitably conductive materials. In one or more embodiments, the metal layers 104 are each a layer stack of a first transparent conductive oxide (TCO) layer, a second metal-containing layer disposed on the first TCO layer, and a third TCO layer disposed on the second metal-containing layer.

The PDL structures 126 are disposed on or over the substrate 102. The PDL structures 126 include one of an organic material, an organic material with an inorganic coating disposed thereover, or an inorganic material. The organic material of the PDL structures 126 includes, but is not limited to, polyimides. The inorganic material of the PDL structures 126 includes, but is not limited to, silicon oxide (SiO₂), silicon nitride (Si₃N₄), silicon oxynitride (Si₂N₂O), magnesium fluoride (MgF₂), or combinations thereof. Adjacent PDL structures 126 define a respective sub-pixel and expose the anode (i.e., metal layer 104) of the respective sub-pixel of the sub-pixel circuit 100.

The sub-pixel circuit 100 has a plurality of sub-pixels 108 including at least a first sub-pixel 108a and a second sub-pixel 108B. While the Figures depict the first sub-pixel 108a and the second sub-pixel 108B. The sub-pixel circuit 100 of the embodiments described herein may include two or more sub-pixels 108, such as a third and a fourth sub-pixel. Each sub-pixel 108 has an OLED material 112 configured to emit a white, red, green, blue or other color light when energized. E.g., the OLED material 112 of the first sub-pixel 108a emits a green light when energized, the OLED material of the second sub-pixel 108B emits a red light when energized, the OLED material of a third sub-pixel emits a blue light when energized, and the OLED material of a fourth sub-pixel emits another color light when energized

Inorganic overhang structures 110 are disposed on or over an upper surface of each of the PDL structures 126. The inorganic overhang structures 110 are permanent to the sub-pixel circuit. The inorganic overhang structures 110 further define each sub-pixel 108 of the sub-pixel circuit 100. The inorganic overhang structures 110 include at least an upper portion 110B disposed on or over a lower portion 110A. A first configuration of the inorganic overhang structures 110 includes the upper portion 110B of a non-conductive inorganic material and the lower portion 110A of a conductive inorganic material. A second configuration of the inorganic overhang structures 110 includes the upper portion 110B of a conductive inorganic material and the lower portion 110A of a conductive inorganic material. A third configuration of the inorganic overhang structures 110 includes the upper portion 110B of a non-conductive inorganic material, the lower portion 110A of a non-conductive inorganic material, and an assistant cathode disposed under the lower portion 110A. A fourth configuration of the inorganic overhang structures 110 includes the upper portion 110B of a conductive inorganic material, the lower portion 110A of a non-conductive inorganic material, and an assistant cathode disposed under the lower portion 110A. It is contemplated that in one or more embodiments, the first configuration and the second configuration further include an assistant cathode disposed under the lower portion 110A. The first, second, third, and fourth exemplary embodiments of the sub-pixel circuit 100 include inorganic overhang structures 110 of at least one of the first, second, third, or fourth configurations. The inorganic overhang structures 110 are able to remain in place, i.e., are permanent. Thus, organic material from lifted off overhang structures that disrupt OLED performance would not be left behind. Eliminating the need for a lift-off procedure also increases throughput.

The non-conductive inorganic material includes, but it not limited to, an inorganic silicon-containing material. E.g., the silicon-containing material includes oxides or nitrides of silicon, or combinations thereof. The conductive inorganic material includes, but it not limited to, a metal-containing material. E.g., the metal-containing material includes copper, titanium, aluminum, molybdenum, silver, indium tin oxide, indium zinc oxide, chromium or combinations thereof.

At least a bottom surface 107 of the upper portion 110B is wider than a top surface 105 of the lower portion 110A to form an overhang 109. The bottom surface 107 larger than the top surface 105 forming the overhang 109 allows for the upper portion 110B to shadow the lower portion 110A. The shadowing of the overhang 109 provides for evaporation deposition each of the OLED material 112 and a cathode 114.

The OLED material 112 may include one or more of a HIL, a HTL, an EML, and an ETL. The OLED material 112 is disposed on the metal layer 104. In some embodiments, which can be combined with other embodiments described herein, the OLED material 112 is disposed on the metal layer 104 and over a portion of the PDL structures 126. The cathode 114 is disposed on or over the OLED material 112 of the PDL structures 126 in each sub-pixel 108. The cathode 114 includes a conductive material, such as a metal. E.g., the cathode 114 includes but is not limited to, silver, chromium, titanium, aluminum, ITO, or a combination thereof. The assistant cathode includes, but it not limited to, a metal-containing material. For example, the metal-containing material includes copper, titanium, aluminum, molybdenum, silver, indium tin oxide, indium zinc oxide, chromium or combinations thereof.

Each sub-pixel 108 includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the inorganic overhang structures 110 and along a sidewall of each of the inorganic overhang structures 110. The encapsulation layer 116 is disposed over the cathode 114 and over at least the sidewall 111 of the lower portion 110A. In some embodiments, which can be combined with other embodiments described herein, the encapsulation layer 116 is disposed over the upper sidewall 113 of the upper portion 110B. The encapsulation layer 116 includes the non-conductive inorganic material, such as the silicon-containing material. The silicon-containing material may include Si₃N₄ containing materials.

In embodiments including one or more capping layers, the capping layers are disposed between the cathode 114 and the encapsulation layer 116. While FIG. 1A depicts the sub-pixel circuit 100 without any capping layers, each of the embodiments described herein may include one or more capping layers disposed between the cathode 114 and the encapsulation layer 116.

The sub-pixel circuit 100 further includes at least a global encapsulation layer 120 disposed over the inorganic overhang structures 110 and the encapsulation layers 116. An intermediate encapsulation layer 118 may be disposed between the global encapsulation layer 120 and a top surface 115 of the upper portion 110B the inorganic overhang structures 110 and the encapsulation layers 116. The intermediate encapsulation layer 118 may include an acrylic material.

FIG. 1B is a schematic, top view of a sub-pixel circuit 100 having a dot-type architecture 101A, according to one or more embodiments. FIG. 1C is a schematic, top view of a sub-pixel circuit 100 having a line-type architecture 101B, according to one or more embodiments.

The dot-type architecture 101A includes a plurality of pixel openings 124A. Each of pixel opening 124A is surrounded by inorganic overhang structures 110 that define each of the sub-pixels 108 of the dot-type architecture 101A. The line-type architecture 101B includes a plurality of pixel openings 124B. Each of pixel opening 124B is abutted by inorganic overhang structures 110 that define each of the sub-pixels 108 of the line-type architecture 101B.

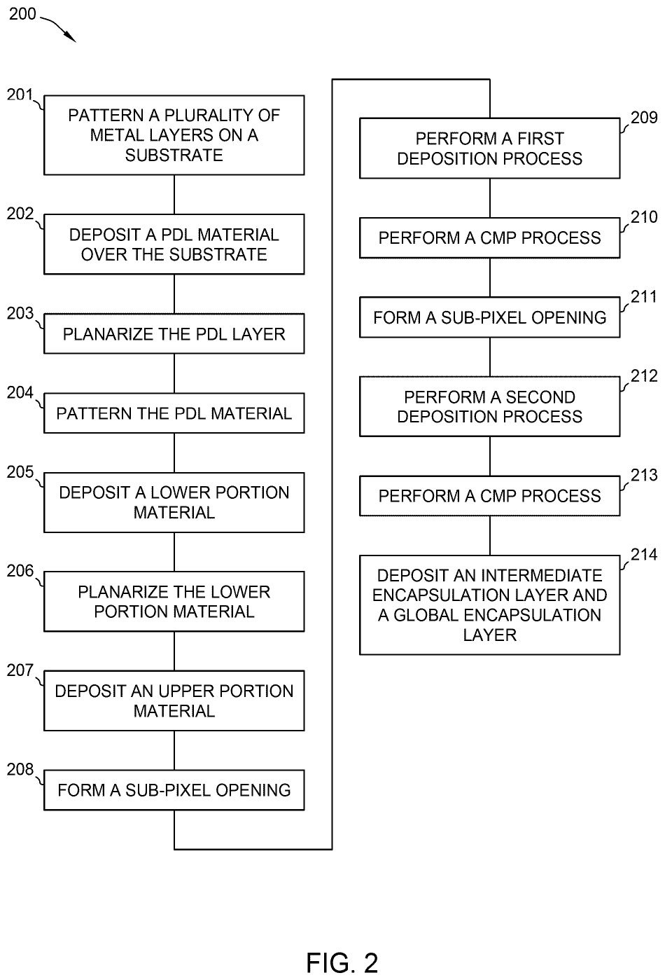

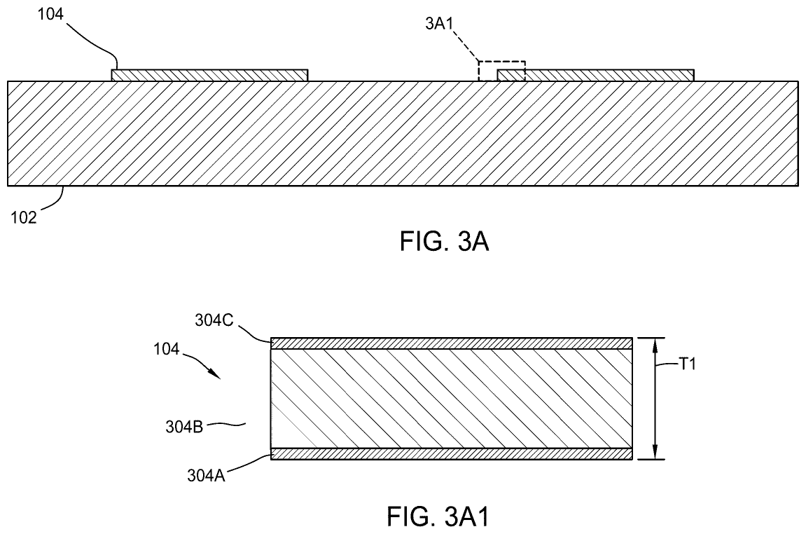

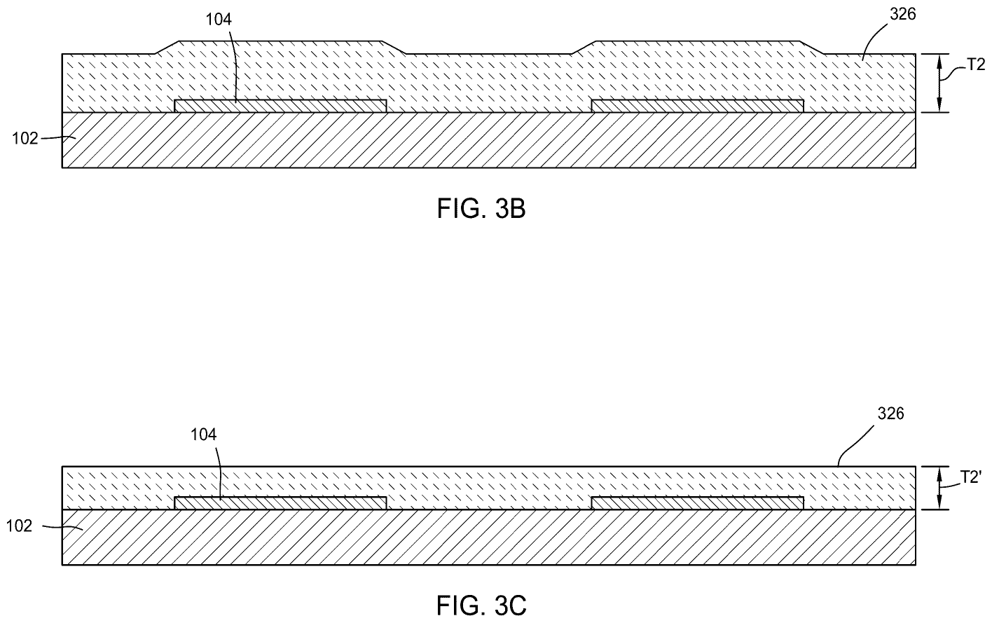

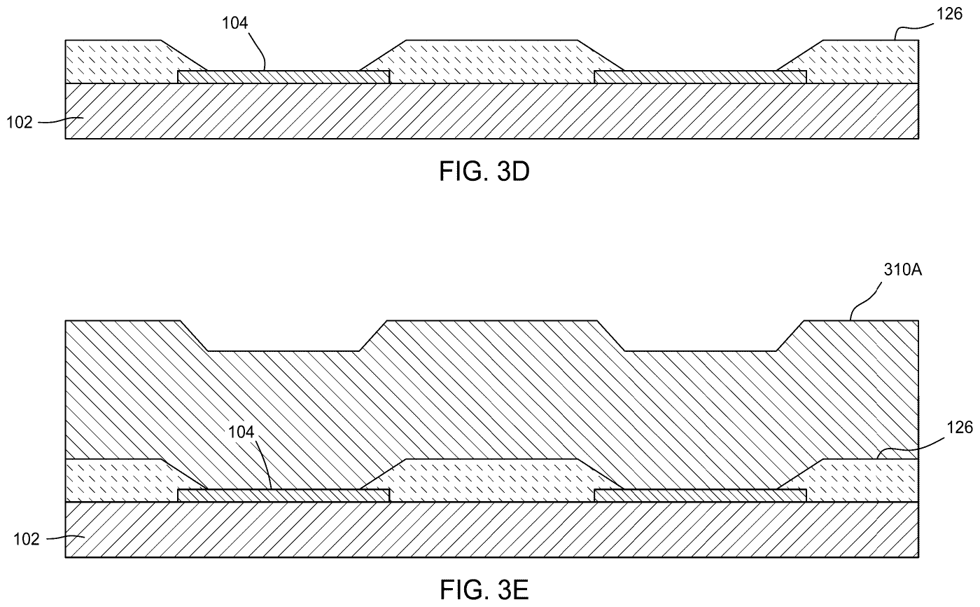

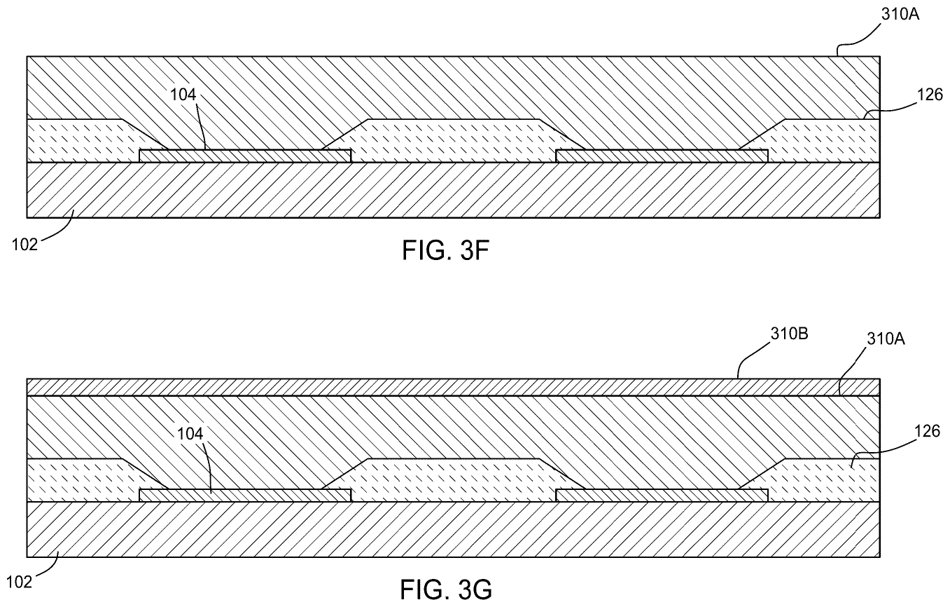

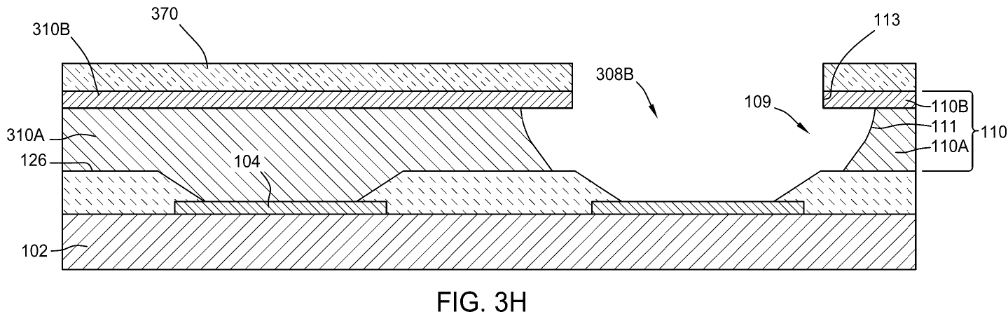

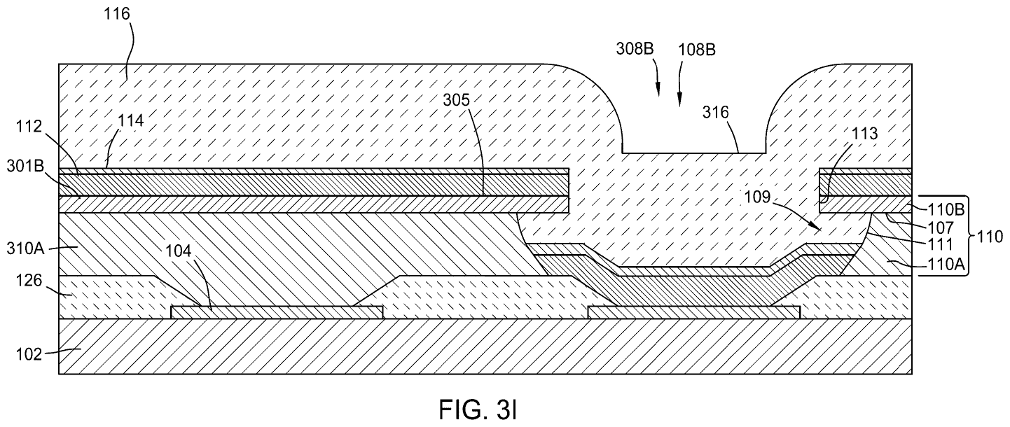

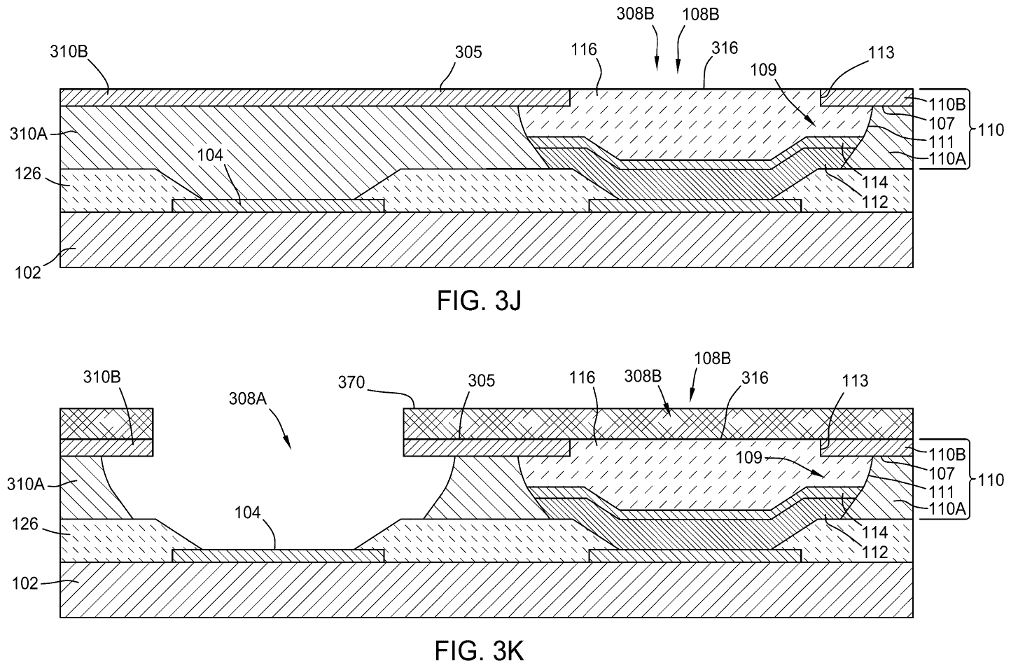

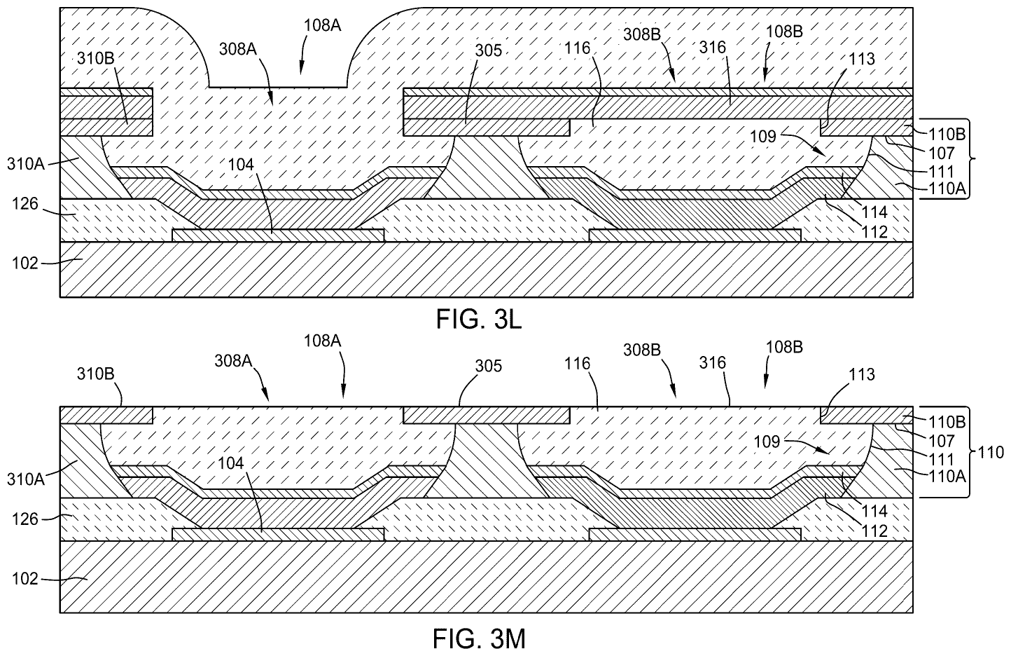

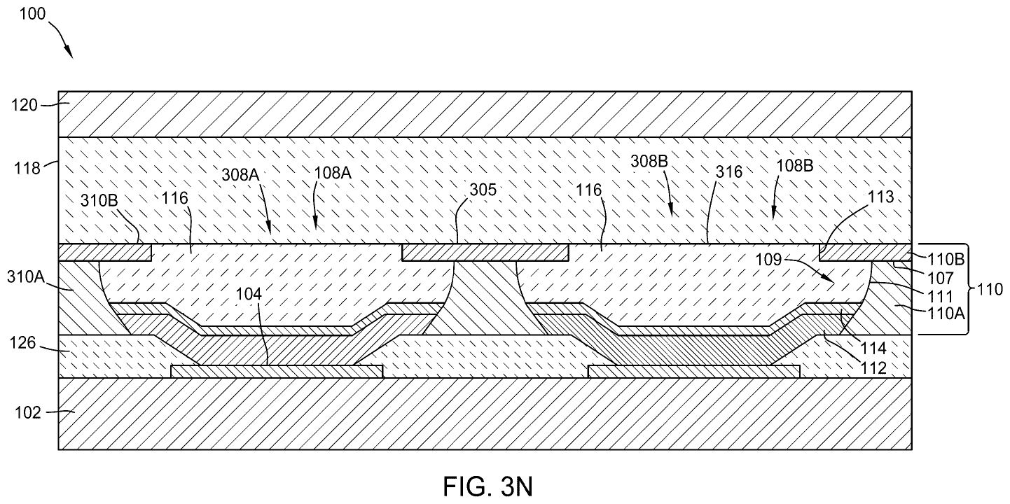

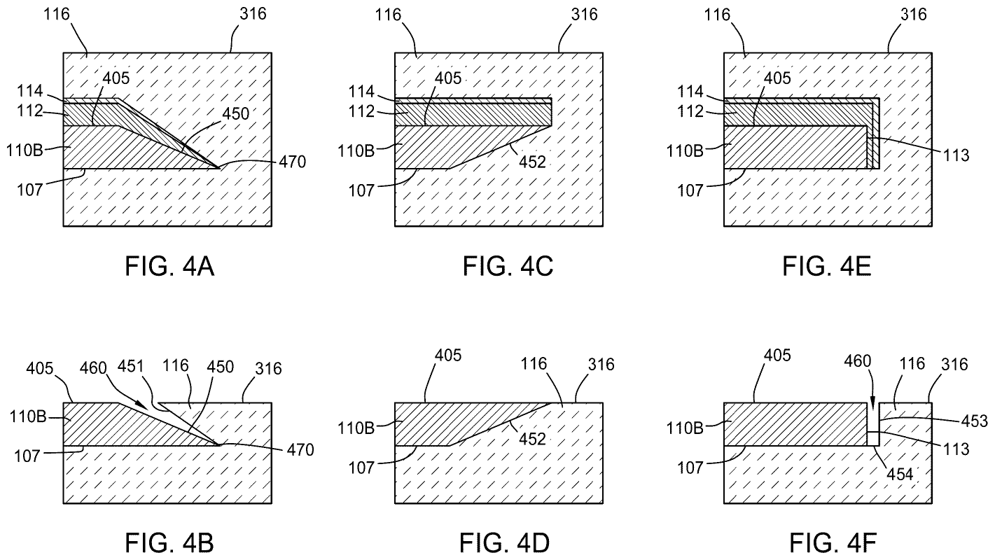

FIG. 2 is a flow a flow diagram of an on-demand CMP method 200 for forming a sub-pixel circuit 100, according to one or more embodiments. The on-demand CMP method 200 corresponds to the on-demand method to fabricate a sub-pixel circuit 100 having either a dot-type architecture 101A or a line type architecture 101B. FIGS. 3A-4N are schematic, cross-sectional views of a substrate 102 during the method 200 for forming the sub-pixel circuit 100, according to embodiments.

At operation 201, as shown in FIG. 3A, a plurality of metal layers 104 are patterned on or over a substrate 102. In one or more embodiments, the metal layers 104 are formed of a plurality of layers. FIG. 3A1 is a close up schematic cross-section of a portion of a metal layer 104. The metal layer 104 includes a first layer 304A. The first layer 304A is formed from a first material including indium tin oxide (ITO). A second layer 304B is formed over the first layer 304A. The second layer 304B is formed from a second material including silver (Ag). A third layer 304C is formed over the second layer 304B. The third layer 304C is formed from a third material including ITO. In one or more embodiments, the first material and the third material are the same. The metal layer 104 has a thickness T1. The thickness T1 is from about 100 nm to about 200 nm.

At operation 202, as shown in FIG. 3B, a PDL material 326 is deposited over the substrate 102 and the metal layers 104. In one or more embodiments, PDL material includes silicon nitride (SiNₓ). The PDL material has a PDL material thickness T2 when it is deposited. The PDL material thickness T2 is from about 100 nm to about 1000 nm.

At operation 203, as shown in FIG. 3C, the PDL material 326 is planarized using a chemical mechanical planarization (CMP) process. The PDL material thickness T2 is changed to a planarized PDL material thickness T2′. The planarized PDL material thickness T2′ is from about 100 nm to about 800 nm. It is contemplated that in one or more embodiments, operation 203 is optional in performing method 200.

At operation 204, as shown in FIG. 3D a patterning process is performed on the PDL material 326 to form the PDL structures 126. During the patterning process a photoresist is deposited over the PDL material 326. The desired pattern is then patterned into the photoresist using a photolithography process. After the photolithography process the desired portions of the photoresist are removed exposing the PDL material 326 beneath the photoresist. A dry etching process is performed on the exposed areas of the PDL material. The exposed areas of the PDL material 326 are etched away in order to expose a portion of each of the metal layers 104. After the dry etching process is completed the remaining photoresist is stripped away forming the PDL structures.

At operation 205, as shown in FIG. 3E, a lower portion material 310A is deposited over the metal layers 104 and the PDL structures 126. The lower portion material 310A can include conductive inorganic materials or non-conductive inorganic materials. The lower portion material 310A includes the same material as the lower portion 110A of the overhang structure. At operation 206, as shown in FIG. 3F, the lower portion material 310A is planarized using a chemical mechanical planarization (CMP) process. At operation 207, as shown in FIG. 3G, an upper portion material 310B is deposited over the lower portion material 310A. The upper portion material 310B can include conductive inorganic materials or non-conductive inorganic materials. The upper portion material 310B includes the same material as the upper portion 110B of the overhang structure. The non-conductive inorganic materials includes, but are not limited to, an inorganic silicon-containing material. For example, the silicon-containing materials include oxides or nitrides of silicon, or combinations thereof. The conductive inorganic material include, but are not limited to, a metal-containing materials. For example, the metal-containing materials include copper, titanium, aluminum, molybdenum, silver, indium tin oxide, indium zinc oxide, chromium or combinations thereof.

At operation 208, as shown in FIG. 3H, a second sub-pixel opening 308B is formed in the upper portion material 310B and the lower portion material 310A. The second sub-pixel opening 308B is patterned using a photolithography process. During the photolithography process a photoresist 370 is deposited on or over the upper portion material 310B. After the photolithography process a desired portion of the photoresist 370 is removed, exposing the upper portion material 310B. The exposed portion of the upper portion material 310B and the lower portion material 310A is etched away to form the second sub-pixel opening 308B. Adjacent overhang structures 110 are formed during the etching process and at least partially define the second sub-pixel opening 308B. A portion of the metal layer 104 as well as a portion of adjacent PDL structures 126 are exposed by the second sub-pixel opening 308B. The lower sidewalls 111 and the upper sidewalls 113 of the adjacent overhang structures 110 are exposed by the second sub-pixel opening 308B.

At operation 209, as shown in FIG. 3I, a first deposition process is performed. During the deposition process, the OLED material 112 for the second sub-pixel 108B is deposited within the second sub-pixel opening 308B. The OLED material 112 is deposited over the exposed portion of the metal layers 104 and extends over the exposed portion of the adjacent PDL structures 126. The OLED material 112 extends under at least a portion of the overhang 109 of the overhang structures 110. In one or more embodiments, the OLED material 112 contacts the lower sidewall 111 of the adjacent overhang structures 110. The OLED material 112 is further deposited over on or over the upper portion material 310B. In one or more embodiments, the OLED material 112 is further deposited over the upper sidewall 113 of the adjacent overhang structures 110. The cathode 114 is deposited on or over the OLED material 112. An encapsulation layer 116 is deposited on or over the cathode 114 to complete the second sub-pixel 108B. In one or more embodiments, the encapsulation layer 116 fills the second sub-pixel opening 308B and contacts the bottom surface 107 of the upper portion 110B of the adjacent overhang structures 110. The encapsulation layer 116 includes an upper sub-pixel surface 316. The upper sub-pixel surface 316 extends over at least a portion of the second sub-pixel opening 308B. FIG. 3I shows the upper sub-pixel surface 316 located above an upper surface 305 of the upper portion 110B of the adjacent overhang structures 110. The upper sub-pixel surface 316 can be located below an upper surface 305 of the upper portion 110B of the adjacent overhang structures 110, such as below contacts the bottom surface 107 of the upper portion 110B of the adjacent overhang structures 110.

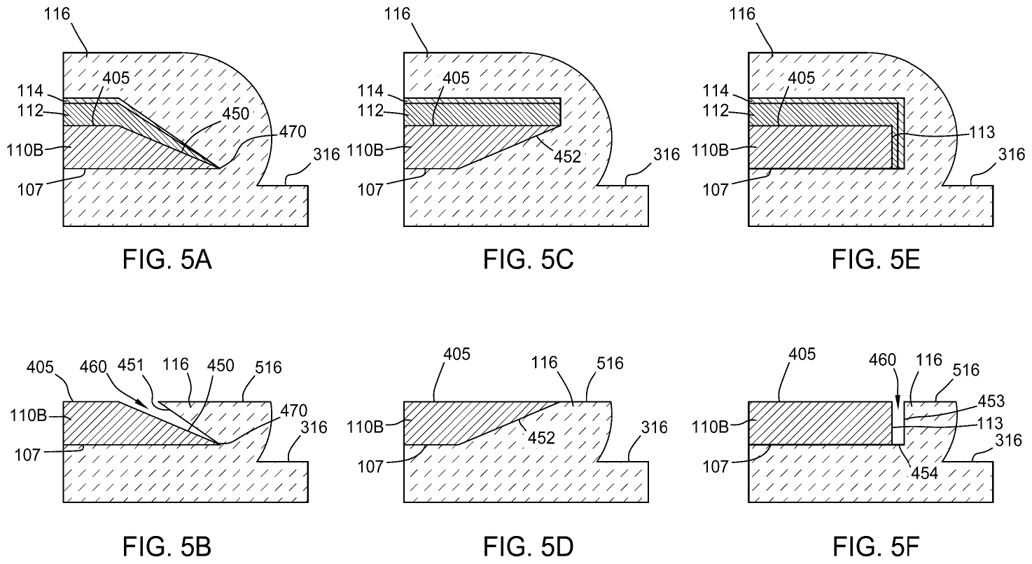

At operation 210, as shown in FIG. 3J, a CMP process is performed. During the CMP process the encapsulation layer 116, the cathode 114, and the OLED material 112 deposited on or over the upper surface 305 of the upper portion material 310B are removed by a CMP process. A portion of the encapsulation layer 116 deposited over the second sub-pixel opening 308B is planarized by the CMP process. In one or more embodiments where the upper sub-pixel surface 316 of the encapsulation layer 116 is above the upper surface 305 of the upper portion material 310B, as shown in FIG. 3J the upper sub-pixel surface 316 of the encapsulation layer 116 is planarized. After the CMP process is performed, the upper surface 305 of the upper portion material 310B and the upper sub-pixel surface 316 of the encapsulation layer 116 are coplanar. In one or more embodiments, the upper sub-pixel surface 316 of the encapsulation layer 116 is below the upper surface 305 of the upper portion material 310B, a CMP process is performed on the encapsulation layer 116 and a portion of an upper surface of the encapsulation layer 116 is planarized to be co-planar to the upper surface 305 of the upper portion material 310B. The upper sub-pixel surface 316 of the encapsulation layer 116 is not planarized by the CMP process. The embodiments where the upper sub-pixel surface 316 of the encapsulation layer 116 is below the upper surface 305 of the upper portion material 310B are described in greater detail in FIGS. 5A-5F. It is contemplated that a wet-etch process and/or dry etch process may be performed after the CMP process in order to remove excess OLED material 112 and cathode 114 deposited on or over the upper portion 110B of the overhang structures 110.

At operation 211, as shown in FIG. 3K, a first sub-pixel opening 308A is formed in the upper portion material 310B and the lower portion material 310A adjacent to the second sub-pixel opening 308B. The first sub-pixel opening 308A is patterned using a photolithography process. During the photolithography process a photoresist 370 is deposited on or over the upper portion material 310B. After the photolithography process a desired portion of the photoresist 370 is removed, exposing the upper portion material 310B. The exposed portion of the upper portion material 310B and the lower portion material 310A is etched away to form the first sub-pixel opening 308A. Adjacent overhang structures 110 are formed during the etching process and at least partially define first sub-pixel opening 308A. A portion of the metal layer 104 as well as a portion of adjacent PDL structures 126 are exposed by the second sub-pixel opening 308B. The lower sidewalls 111 and the upper sidewalls 113 of the adjacent overhang structures 110 are exposed by the second sub-pixel opening 308B.

At operation 212, as shown in FIG. 3L, a second deposition process is performed. During the deposition process, the OLED material 112 for the first sub-pixel 108a is deposited within the first sub-pixel opening 308A. The OLED material 112 is deposited over the exposed portion of the metal layer 104 and extends over the exposed portion of the adjacent PDL structures 126. The OLED material 112 extends under at least a portion of the overhang 109 of the overhang structures 110. In one or more embodiments, the OLED material 112 contacts the lower sidewall 111 of the adjacent overhang structures 110. The OLED material 112 is further deposited over the upper surface 305 of the upper portion 110B of the overhang structures 110, and the upper sub-pixel surface 316 of the encapsulation layer 116 in the second sub-pixel opening 308B. In one or more embodiments, the OLED material 112 is further deposited over the upper sidewall 113 of the adjacent overhang structures 110. The cathode 114 is deposited over the OLED material 112. An encapsulation layer 116 is deposited the cathode 114 to complete the first sub-pixel 108a. In one or more embodiments, the encapsulation layer 116 fills the first sub-pixel opening 308A and contacts the bottom surface 107 of the upper portion 110B of the adjacent overhang structures 110. The encapsulation layer 116 includes an upper sub-pixel surface 316. The upper sub-pixel surface 316 extends over at least a portion of the first sub-pixel opening 308A. FIG. 3I shows the upper sub-pixel surface 316 located above an upper surface 305 of the upper portion 110B of the adjacent overhang structures 110. The upper sub-pixel surface 316 can be located below an upper surface 305 of the upper portion 110B of the adjacent overhang structures 110, such as below contacts the bottom surface 107 of the upper portion 110B of the adjacent overhang structures 110.

At operation 213, as shown in FIG. 3M, a CMP process is performed. During the CMP process the encapsulation layer 116, the cathode 114, and the OLED material 112 deposited on or over the upper surface 305 of the upper portion material 310B are removed by a CMP process. A portion of the encapsulation layer 116 deposited over the second sub-pixel opening 308B is planarized by the CMP process. In one or more embodiments, where the upper sub-pixel surface 316 of the encapsulation layer 116 is above the upper surface 305 of the upper portion material 310B, as shown in FIG. 3M the upper sub-pixel surface 316 of the encapsulation layer 116 is planarized. After the CMP process is performed, the upper surface 305 of the upper portion material 310B and the upper sub-pixel surface 316 of the encapsulation layer 116 are coplanar. In one or more embodiments the upper sub-pixel surface 316 of the encapsulation layer 116 is below the upper surface 305 of the upper portion material 310B, a CMP process is performed on the encapsulation layer 116 and a portion of an upper surface of the encapsulation layer 116 is planarized to be co-planar to the upper surface 305 of the upper portion material 310B. The upper sub-pixel surface 316 of the encapsulation layer 116 is not planarized by the CMP process. The embodiments where the upper sub-pixel surface 316 of the encapsulation layer 116 is below the upper surface 305 of the upper portion material 310B are described in greater detail in FIGS. 5A-5F. It is contemplated that a wet-etch process may be performed after the CMP process in order to remove excess OLED material 112 and cathode 114 deposited on or over the upper portion 110B of the overhang structures 110.

At operation 214, as shown in FIG. 3N, the intermediate encapsulation layer 118 and the global encapsulation layer 120 are deposited over the encapsulation layer 116 within first sub-pixel 108a and the second sub-pixel 108B, as well as the upper surface 305 of the upper portion 110B of the adjacent overhang structures 110, completing the sub-pixel circuit 100.

FIGS. 4A-4F are a close-up schematic, cross-sectional view of an upper portion 110B of the overhang structure 110 of a sub-pixel circuit, according to embodiments. FIGS. 4A and 4B show an upper portion 110B having an upper sloped sidewall 450, according to embodiments. In FIG. 4A, an OLED material 112, a cathode 114, and an encapsulation layer 116 are deposited over the upper surface 405 and the upper sloped sidewall 450 of the upper portion 110B of the overhang structure 110 as described in operation 209 of method 200. The encapsulation layer has an upper sub-pixel surface 316 above the upper surface 405 of the upper portion 110B.

FIG. 4B shows the upper portion 110B having an upper sloped sidewall 450 of FIG. 4A after a CMP process as described in operation 210 of method 200. During the CMP process the portion of the OLED material 112, the cathode 114, and the encapsulation layer 116 disposed over the upper surface 405 of the upper portion 110B are removed. The upper sub-pixel surface 316 is planarized so that the upper sub-pixel surface 316 is coplanar to the upper surface 405 of the upper portion 110B. After the CMP process a wet etch process and/or dry etch process is performed to remove the portion of the OLED material 112 and the cathode 114 deposited over the upper sloped sidewall 450. After the etch process is performed, a gap 460 is formed between the upper sloped sidewall 450 and a sloped lower surface 451 of the encapsulation layer 116. The upper sloped sidewall 450 and the sloped lower surface 451 contact at a lower edge 470. The lower edge 470 is defined by where the upper sloped sidewall 450 and the bottom surface 107 meet. In one or more embodiments, when the intermediate encapsulation layer 118 is deposited over the upper portion 110B and the encapsulation layer 116 as described in operation 214 of method 200, the intermediate encapsulation layer fills the gap 460.

FIGS. 4C and 4D show an upper portion 110B having a sloped lower sidewall 452, according to embodiments. In FIG. 4C, an OLED material 112, a cathode 114, and an encapsulation layer 116 are deposited over the upper portion 110B of the overhang structure 110 as described in operation 209 of method 200. The encapsulation layer has an upper sub-pixel surface 316 above the upper surface 405 of the upper portion 110B.

FIG. 4D shows the upper portion 110B having a sloped lower sidewall 450 452 of FIG. 4C after a CMP process as described in operation 210 of method 200. During the CMP process the portion of the OLED material 112, the cathode 114, and the encapsulation layer 116 disposed over the upper surface 405 of the upper portion 110B are removed. The upper sub-pixel surface 316 is planarized so that the upper sub-pixel surface 316 is coplanar to the upper surface 405 of the upper portion 110B.

FIGS. 4E and 4F show an upper portion 110B having an upper sidewall 113 as shown in FIG. 1. The bottom surface 107 of the upper portion 110B has a first width. The upper surface 405 of the upper portion 110B has a second width. The first width and the second width are equivalent. In FIG. 4E, an OLED material 112, a cathode 114, and an encapsulation layer 116 are deposited over the upper surface 405 upper portion 110B of the overhang structure 110 as well as the upper sidewall 113 of the upper portion 110B of the overhang structure 110, as described in operation 209 of method 200. The encapsulation layer has an upper sub-pixel surface 316 above the upper surface 405 of the upper portion 110B.

FIG. 4F shows the upper portion 110B having an upper sidewall 113 of FIG. 4E after a CMP process as described in operation 210 of method 200. During the CMP process the portion of the OLED material 112, the cathode 114, and the encapsulation layer 116 disposed over the upper surface 405 of the upper portion 110B are removed. The upper sub-pixel surface 316 is planarized so that the upper sub-pixel surface 316 is coplanar to the upper surface 405 of the upper portion 110B. After the CMP process is performed a wet etch process and or dry etch process is performed to remove the portion of the OLED material 112 and the cathode 114 deposited over the sidewall. After the etch process is performed, a gap 460 is formed between the upper sidewall 113 and an encapsulation sidewall 453 of the encapsulation layer 116. The encapsulation sidewall 453 is parallel to the upper sidewall 113. The encapsulation layer 116 further includes a lower encapsulation surface 454 between the upper sidewall 113 and the encapsulation sidewall 453. The lower encapsulation surface 454 is coplanar to the bottom surface 107 of the upper portion 110B. In one or more embodiments, when the intermediate encapsulation layer 118 is deposited over the upper portion 110B and the encapsulation layer 116 as described in operation 214 of method 200, the intermediate encapsulation layer fills the gap 460. In FIGS. 4A-4F the upper sub-pixel surface 316 is an uppermost surface of the encapsulation layer.

FIGS. 5A-5F are a close-up schematic, cross-sectional view of an upper portion 110B of the overhang structure 110 of a sub-pixel circuit, according to embodiments. FIGS. 5A-5F include an encapsulation layer 116 having an upper sub-pixel surface 316 disposed below an upper surface 405 of the upper portion 110B. In FIGS. 5A-5F the upper sub-pixel surface 316 disposed below the bottom surface 107 of the upper portion 110B, however, it should be understood that the upper pixel surface can be disposed anywhere below the upper surface 405 of the upper portion 110B FIGS. 5A and 5B show an upper portion 110B having an upper sloped sidewall 450, according to embodiments. In FIG. 5A, an OLED material 112, a cathode 114, and an encapsulation layer 116 are deposited over the upper surface 405 and the upper sloped sidewall 450 of the upper portion 110B of the overhang structure 110 as described in operation 209 of method 200. The encapsulation layer 116 has an upper sub-pixel surface 316 below the upper surface 405 of the upper portion 110B.

FIG. 5B shows the upper portion 110B having an upper sloped sidewall 450 of FIG. 5A after a CMP process as described in operation 210 of method 200. During the CMP process the portion of the OLED material 112, the cathode 114, and the encapsulation layer 116 disposed over the upper surface 405 of the upper portion 110B are removed. The encapsulation layer 116 is planarized to form an upper planarized surface 516. The upper planarized surface 516 is coplanar to the upper surface 405. After the CMP process is performed a wet etch process and or dry etch process is performed to remove the portion of the OLED material 112 and the cathode 114 deposited over the upper sloped sidewall 450. After the etch process is performed, a gap 460 is formed between the upper sloped sidewall 450 and a sloped lower surface 451 of the encapsulation layer 116. The upper sloped sidewall 450 and the sloped lower surface 451 contact at a lower edge 470. The lower edge 470 is defined by where the upper sloped sidewall 450 and the bottom surface 107 meet. In one or more embodiments, when the intermediate encapsulation layer 118 is deposited over the upper portion 110B and the encapsulation layer 116 as described in operation 214 of method 200, the intermediate encapsulation layer fills the gap 460.

FIGS. 5C and 5D show an upper portion 110B having a sloped lower sidewall 452, according to embodiments. In FIG. 5C, an OLED material 112, a cathode 114, and an encapsulation layer 116 are deposited over the upper portion 110B of the overhang structure 110 as described in operation 209 of method 200. The encapsulation layer 116 has an upper sub-pixel surface 316 below the upper surface 405 of the upper portion 110B.

FIG. 5D shows the upper portion 110B having a sloped lower sidewall 450 452 of FIG. 4C after a CMP process as described in operation 210 of method 200. During the CMP process the portion of the OLED material 112, the cathode 114, and the encapsulation layer 116 disposed over the upper surface 405 of the upper portion 110B are removed. The encapsulation layer 116 is planarized to form an upper planarized surface 516. The upper planarized surface 516 is coplanar to the upper surface 405.

FIGS. 5E and 5F show an upper portion 110B having an upper sidewall 113 as shown in FIG. 1. The bottom surface 107 of the upper portion 110B has a first width. The upper surface 405 of the upper portion 110B has a second width. The first width and the second width are equivalent. In FIG. 5E, an OLED material 112, a cathode 114, and an encapsulation layer 116 are deposited over the upper surface 405 of the upper portion 110B of the overhang structure 110 as well as the upper sidewall 113 of the upper portion 110B of the overhang structure 110, as described in operation 209 of method 200. The encapsulation layer 116 has an upper sub-pixel surface 316 below the upper surface 405 of the upper portion 110B.

FIG. 5F shows the upper portion 110B having an upper sidewall 113 of FIG. 5E after a CMP process as described in operation 210 of method 200. During the CMP process the portion of the OLED material 112, the cathode 114, and the encapsulation layer 116 disposed over the upper surface 405 of the upper portion 110B are removed. The encapsulation layer 116 is planarized to form an upper planarized surface 516. The upper planarized surface 516 is coplanar to the upper surface 405. After the CMP process is performed a wet etch process and or dry etch process is performed to remove the portion of the OLED material 112 and the cathode 114 deposited over the sidewall. After the etch process is performed, a gap 460 is formed between the having an upper sidewall 113 and an encapsulation sidewall 453 of the encapsulation layer 116. The encapsulation sidewall 453 is parallel to the upper sidewall 113. The encapsulation layer 116 further includes a lower encapsulation surface 454 between the upper sidewall 113 and the encapsulation sidewall 453. The lower encapsulation surface 454 is coplanar to the bottom surface 107 of the upper portion 110B. In one or more embodiments, when the intermediate encapsulation layer 118 is deposited over the upper portion 110B and the encapsulation layer 116 as described in operation 214 of method 200, the intermediate encapsulation layer fills the gap 460. In FIGS. 5A-5F the upper planarized surface 516 is an uppermost surface of the encapsulation layer.

Benefits of the present disclosure include a method of forming a sub-pixel circuit 100 by removing the encapsulation layer 116 using a CMP process. Removing the encapsulation layer 116 with a CMP process requires less photolithography processes to form the sub-pixel circuit 100. Less photolithography processes leads to a decreased chance of damaging the sub-pixels, as well as decreased residue from the etching process. The CMP process also allows for the sub-pixel circuit to be formed in a decreased amount of operations, which in turn allows for a decreased manufacturing time, decreased cost, and decreased maintenance when manufacturing the sub-pixel circuit 100.

It is contemplated that one or more aspects disclosed herein may be combined. As an example, one or more aspects, features, components, operations and/or properties of the sub-pixel circuit 100, the substrate 102, the metal layers 104, the PDL structures 126, the first sub-pixel 108a, the second sub-pixel 108B, the overhang structures 110, the OLED material 112, the cathode 114, the overhang 109, the encapsulation layer 116, the intermediate encapsulation layer 118, the global encapsulation layer 120, the method 200, the first layer 304A, the second layer 304B, A third layer 304C, the PDL material 326, the lower portion material 310A, the upper portion material 310B, the first sub-pixel opening 308A, and/or the second sub-pixel opening 308B may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A sub-pixel, comprising:
adjacent overhang structures disposed over a substrate, each overhang structure having an upper portion having a top surface and a bottom surface, the bottom surface wider than a top surface of a lower portion, adjacent overhang structures defining an opening of the sub-pixel;
an anode disposed over the substrate between the adjacent overhang structures;
an organic light-emitting diode (OLED) material disposed over the anode;
a cathode disposed over the OLED material; and
an encapsulation layer disposed over the cathode, wherein the encapsulation layer extends under at least a portion of the overhang structures along a sidewall of the lower portion and contacts the bottom surface of the upper portion of the overhang structures, the encapsulation layer having an uppermost surface coplanar to the top surface of the upper portion of the adjacent overhang structures;
an intermediate encapsulation layer deposited over the encapsulation layer, the intermediate encapsulation layer extending over upper portion of the overhang structure; and
a global encapsulation layer deposited over the intermediate encapsulation layer.

2. The sub-pixel of claim 1, further comprising a gap between a sidewall of the upper portion and the encapsulation layer adjacent to the upper portion.

3. The sub-pixel of claim 1, wherein the top surface of the upper portion is wider than the bottom surface of the upper portion.

4. The sub-pixel of claim 1, wherein the bottom surface of the upper portion is wider than the top surface of the upper portion.

5. The sub-pixel of claim 4, wherein the upper portion further comprises:
an upper sloped sidewall extending between the top surface of the upper portion and the bottom surface of the upper portion, the upper sloped sidewall and the bottom surface of the upper portion meeting at an edge; and
the encapsulation layer comprises a lower sloped surface, the lower sloped surface of the encapsulation layer and the upper sloped sidewall of the upper portion contacting at the edge, wherein a gap is defined between the lower sloped surface of the encapsulation layer and the upper sloped sidewall of the upper portion.

6. The sub-pixel of claim 5, wherein the intermediate encapsulation layer is at least partially deposited within the gap.

7. The sub-pixel of claim 1, wherein the bottom surface of the upper portion has a first width equivalent to a second width of the top surface of the upper portion.

8. The sub-pixel of claim 7, wherein the upper portion further comprises:
an upper sidewall extending between the top surface of the upper portion and the bottom surface of the upper portion; and
the encapsulation layer comprises:
an encapsulation sidewall parallel to the upper sidewall of the upper portion, wherein the upper sidewall of the upper portion and the encapsulation sidewall define a gap; and
a lower encapsulation surface extending between the encapsulation sidewall and the upper sidewall of the upper portion, wherein the lower encapsulation surface and the lower surface of the upper portion are coplanar.

9. The sub-pixel of claim 8, wherein the intermediate encapsulation layer is at least partially deposited within the gap.

10. A device, comprising:
a plurality of sub-pixels, the plurality of sub-pixels comprising at least a first sub-pixel and a second sub-pixel, the first sub-pixel and the second sub-pixel each comprising:
adjacent overhang structures disposed over a substrate, each overhang structure having an upper portion having a top surface and a bottom surface, the bottom surface wider than a top surface of a lower portion, adjacent overhang structures defining an opening of the sub-pixel;
an anode disposed over the substrate between the adjacent overhang structures;
an organic light-emitting diode (OLED) material disposed over the anode;
a cathode disposed over the OLED material; and
an encapsulation layer disposed over the cathode, wherein the encapsulation layer extends under at least a portion of the overhang structures along a sidewall of the lower portion and contacts the bottom surface of the upper portion of the overhang structures, the encapsulation layer having an uppermost surface coplanar to the top surface of the upper portion of the adjacent overhang structures;
an intermediate encapsulation layer deposited over the encapsulation layer, the intermediate encapsulation layer extending over upper portion of the overhang structure; and
a global encapsulation layer deposited over the intermediate encapsulation layer.

11. The device of claim 10, further comprising a gap between a sidewall of the upper portion and the encapsulation layer adjacent to the upper portion.

12. The device of claim 10, wherein the top surface of the upper portion is wider than the bottom surface of the upper portion.

13. The device of claim 10, wherein the bottom surface of the upper portion is wider than the top surface of the upper portion.

14. The device of claim 13, wherein the upper portion further comprises:
an upper sloped sidewall extending between the top surface of the upper portion and the bottom surface of the upper portion, the upper sloped sidewall and the bottom surface of the upper portion meeting at an edge; and
the encapsulation layer comprises a lower sloped surface, the lower sloped surface of the encapsulation layer and the upper sloped sidewall of the upper portion contacting at the edge, wherein a gap is defined between the lower sloped surface of the encapsulation layer and the upper sloped sidewall of the upper portion.

15. The device of claim 14, wherein the intermediate encapsulation layer is at least partially deposited within the gap.

16. The device of claim 10, wherein the bottom surface of the upper portion has a first width equivalent to a second width of the top surface of the upper portion.

17. The device of claim 16, wherein the upper portion further comprises:
an upper sidewall extending between the top surface of the upper portion and the bottom surface of the upper portion; and
the encapsulation layer comprises:
an encapsulation sidewall parallel to the upper sidewall of the upper portion, wherein the upper sidewall of the upper portion and the encapsulation sidewall define a gap; and
a lower encapsulation surface extending between the encapsulation sidewall and the upper sidewall of the upper portion, wherein the lower encapsulation surface and the lower surface of the upper portion are coplanar.

18. The device of claim 17, wherein the intermediate encapsulation layer is at least partially deposited within the gap.

19. A method of manufacturing a sub-pixel device comprising:
depositing a plurality of anodes over a substrate;
patterning a plurality of pixel defining layer (PDL) structures over the substrate;
depositing a lower portion material over the substrate;
depositing an upper portion material over the substrate;
forming a first sub-pixel opening in the lower portion material and the upper portion material; the first sub-pixel opening defining adjacent overhang structures, the adjacent overhang structures having an upper portion having a top surface and a bottom surface, the bottom surface wider than a top surface of a lower portion;
performing a first deposition process, the first deposition process comprising depositing a first OLED material, a first cathode, and a first encapsulation layer within the first sub-pixel opening, a portion of the first OLED material, the first cathode, and the first encapsulation layer extending over an upper surface of the upper portion material; and
performing a first CMP process to remove the portion of the first OLED material, the first cathode, and the first encapsulation layer extending over an upper surface of the upper portion material.

20. The method of claim 19, further comprising:
forming a second sub-pixel opening in the lower portion material and the upper portion material; the second sub-pixel opening defining adjacent overhang structures, the adjacent overhang structures having an upper portion having a top surface and a bottom surface, the bottom surface wider than a top surface of a lower portion;
performing a second deposition process, the second deposition process comprising depositing a second OLED material, a second cathode, and a second encapsulation layer within the second sub-pixel opening, a portion of the second OLED material, the second cathode, and the second encapsulation layer extending over an upper surface of the upper portion material; and
performing a second CMP process to remove the portion of the second OLED material, the second cathode, and the second encapsulation layer extending over an upper surface of the upper portion material.
